(19) United States
(12) Patent Application Publication
(10) Pub. No.: US 2017/0170146 A1
(43) Pub. Date: Jun. 15, 2017

(54) SEMICONDUCTOR DEVICE AND MANUFACTURING METHOD OF THE SAME

(71) Applicant: INDUSTRIAL TECHNOLOGY RESEARCH INSTITUTE, Hsinchu (TW)

(72) Inventors: Chih-Ming SHEN, New Taipei City (TW); Shih-Hsien WU, Taoyuan City (TW); Ming-Ji DAI, Hsinchu City (TW)

(73) Assignee: INDUSTRIAL TECHNOLOGY RESEARCH INSTITUTE, Hsinchu (TW)

(21) Appl. No.: 14/970,444

(22) Filed: Dec. 15, 2015

(51) Int. Cl. H01L 25/065; H01L 23/498; H01L 21/768; H01L 21/683; H01L 21/56

(52) U.S. Cl. CPC H01L 25/0655; H01L 25/0657; H01L 21/6836; H01L 21/565; H01L 21/76877; H01L 23/49816; H01L 23/49838; H01L 2225/06513; H01L 2225/06586

(57) ABSTRACT

A semiconductor device is provided. The semiconductor device includes at least one first die, a rib structure enclosing the at least one first die, and a molding layer covering the at least one first die. The rib structure is formed of a first material and the molding layer is formed of a second material. A Young's modulus of the first material is larger than a Young's modulus of the second material.

### TECHNICAL FIELD

The disclosure relates in general to a semiconductor device and the manufacturing method of the same, and more particularly to a semiconductor device having a rib structure and the manufacturing method of the same.

### BACKGROUND

Fan-out wafer level package (FOWLP) has been a main technology for the recent years, and global packaging manufacturers have put a lot of resources to develop this technology. However, FOWLP usually generates problems, such as die shift and warpage in molded wafers. Larger die shift may affect the alignment of the redistribution layer (RDL) and the die pad during the manufacturing processes. In addition, various apparatus used in the manufacturing processes, such as apparatus for photo-etching pattern of the passivation layer, apparatus for the photoresist process, apparatus for metal-sputtering deposition process, and the like, cannot accept much warpage in molded wafers.

Therefore, it is important in the technical field to enhance the bending strength of the molded wafer, reduce the deformation due to different coefficients of thermal expansion (CTE) of different materials during the manufacturing processes, and solve the problems of die shift and warpage in molded wafers.

### SUMMARY

The disclosure is directed to a semiconductor device having a rib structure and the manufacturing method of the same. The deformation due to different coefficients of thermal expansion (CTE) of different materials during the manufacturing processes may be effectively reduced by the rib structure, such that the problems of die shift and warpage in molded wafers may be solved.

According to one embodiment, a semiconductor device is provided. The semiconductor device includes at least one first die, a rib structure enclosing the at least one first die and formed of a first material, and a molding layer covering the at least one first die and formed of a second material. A Young's modulus of the first material is larger than a Young's modulus of the second material.

According to another embodiment, a semiconductor stacked structure including a plurality of semiconductor devices stacked on top of each other is provided. Each of the semiconductor devices includes at least one first die, a rib structure enclosing the at least one first die and formed of a first material, a molding layer covering the at least one first die and formed of a second material, a redistribution layer electrically connected to the at least one first die, and a plurality of solder balls electrically connected to the redistribution layer. A Young's modulus of the first material is larger than a Young's modulus of the second material. The semiconductor devices are electrically connected to each other by the rib structure, the redistribution layer and the solder balls.

According to an alternative embodiment, a method of manufacturing a semiconductor device is provided. The method includes the following steps. A first adhesive tape is formed on a carrier. A rib structure and at least one first die are formed on the first adhesive tape, and the rib structure encloses the at least one first die. A molding layer is formed on the at least one first die, and spaces between the at least one first die and the rib structure are filled with the molding layer. The molding layer is cured. The first adhesive tape and the carrier are removed. A redistribution layer and a plurality of solder balls electrically connected to the at least one first die are formed. The rib structure is formed of a first material, the molding layer is formed of a second material, and a Young's modulus of the first material is larger than a Young's modulus of the second material.

### BRIEF DESCRIPTION OF THE DRAWINGS

FIG. 1A illustrates a cross-section view of the semiconductor device according to one embodiment of the disclosure.

FIG. 1B illustrates a cross-section view of the semiconductor device according to another embodiment of the disclosure.

FIG. 1C illustrates a top view of the semiconductor device according to the embodiment of the disclosure.

FIG. 2A illustrates a cross-section view of the semiconductor device according to yet another embodiment of the disclosure.

FIG. 2B illustrates a partial top view of the semiconductor device according to the embodiment of the disclosure.

FIG. 3 illustrates a cross-section view of the rib structure according to one embodiment of the disclosure.

FIG. 4 illustrates a schematic diagram of the semiconductor stacked structure according to one embodiment of the disclosure.

FIG. 5 illustrates a cross-section view of the semiconductor device according to still another embodiment of the disclosure.

FIG. 6A to FIG. 6H illustrate a process for manufacturing a semiconductor device in one embodiment according to the disclosure.

FIG. 7A-1 to FIG. 7F illustrate a process for manufacturing a semiconductor device in another embodiment according to the disclosure.

FIG. 8A to FIG. 8H illustrate a process for manufacturing a semiconductor device in one embodiment according to the disclosure.

FIG. 9A-1 to FIG. 9H illustrate a process for manufacturing a semiconductor device in another embodiment according to the disclosure.

FIG. 10 illustrates a cross-section view of the semiconductor device according to another embodiment of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The embodiments are described in details with reference to the accompanying drawings. The identical elements of the embodiments are designated with the same reference numerals. Also, it is important to point out that the illustrations may not be necessarily drawn to scale, and that there may be other embodiments of the present disclosure which are not specifically illustrated. Thus, the specification and the drawings are regarded as an illustrative sense rather than a restrictive sense.

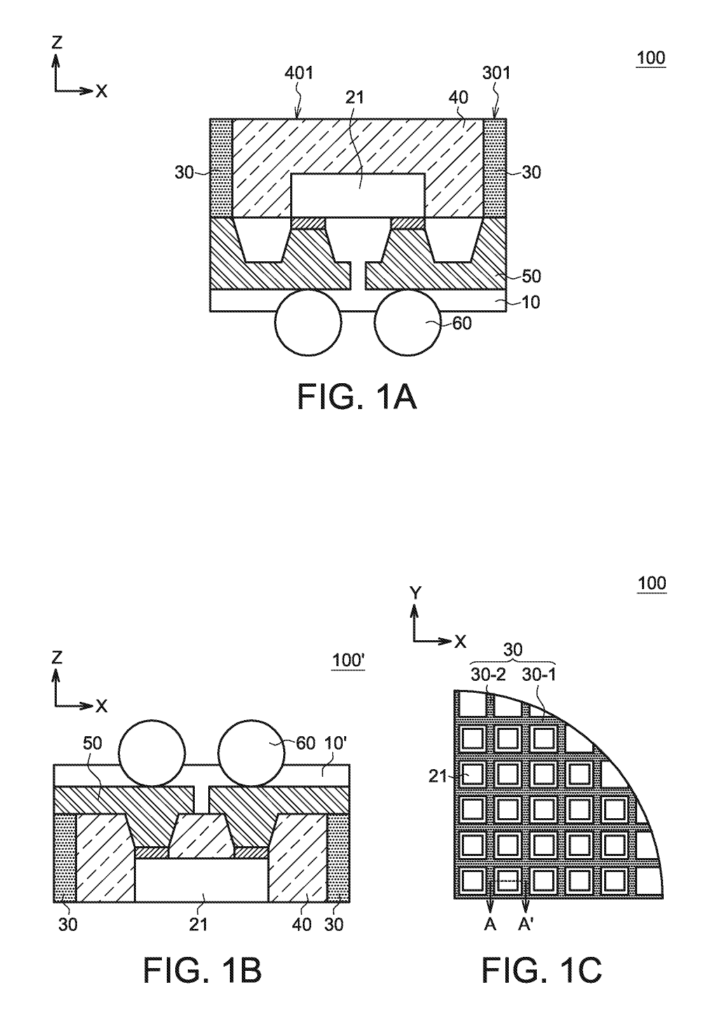

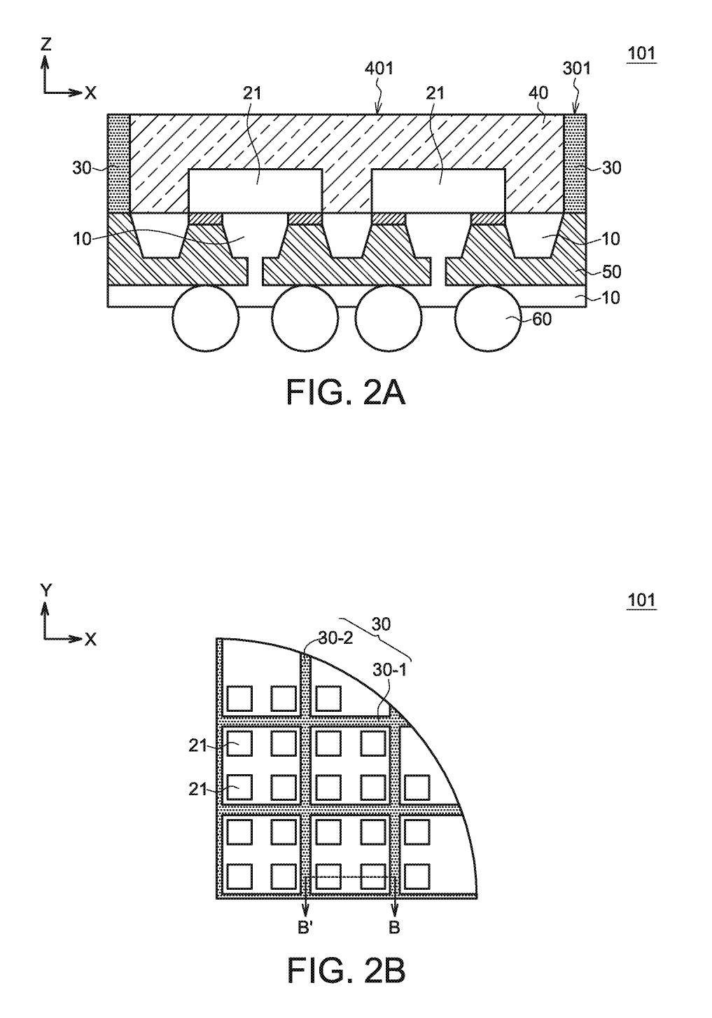

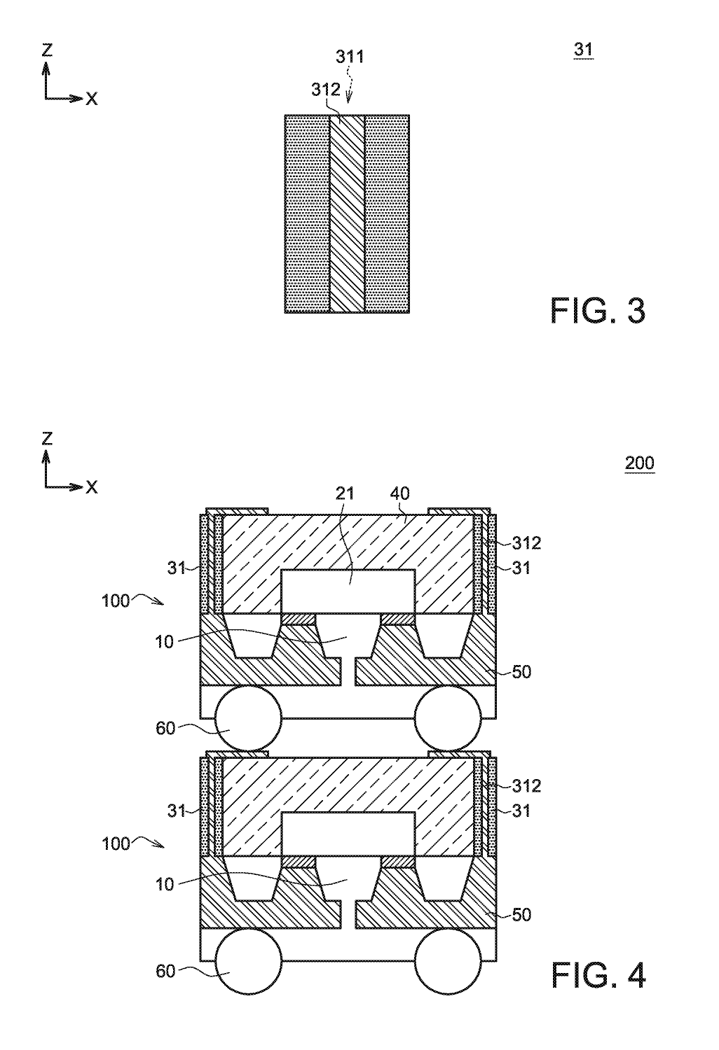

FIG. 1A illustrates a cross-section view of the semiconductor device 100 according to one embodiment of the disclosure. As shown in FIG. 1A, the semiconductor device 100 includes a dielectric layer 10, a first die 21, a rib structure 30 and a molding layer 40. The first die 21 may be disposed on the dielectric layer 10. For example, the dielectric layer 10 may be an adhesive tape, and the first die 21 may be directly affixed to the dielectric layer 10. The rib structure 30 encloses the first die 21, and the molding layer 40 covers the first die 21.

In the embodiment of the disclosure, the rib structure 30 may be formed of a first material, and the molding layer 40 may be formed of a second material. A Young's modulus of the first material is larger than a Young's modulus of the second material. In one embodiment, the first material may be silicon, metal, metal alloy, or ceramic material, while the second material may be molding material, such as epoxy molding compound.

In material mechanics, Young's modulus, which is also known as the elastic modulus, is a mechanical property of linear elastic solid materials. It defines the relationship between stress (force per unit area) and strain (proportional deformation) in a material. The technical definition of Young's modulus is: the ratio of the stress (force per unit area) along an axis to the strain (ratio of deformation over initial length) along that axis in the range of stress in which Hooke's law holds. That is, a stiffness of the rib structure 30 is larger than a stiffness of the molding layer 40. Hence, the rib structure 30 may be a reinforcing structure of the semiconductor device 100, which reduces die shift and warpage in molded wafers due to the different coefficients of thermal expansion of different layers.

As shown in FIG. 1A, the semiconductor device 100 in the embodiment of the disclosure may further include a redistribution layer 50 and a plurality of solder balls 60. The redistribution layer 50 is disposed in the dielectric layer 10, and electrically connected to the first die 21. The solder balls 60 are electrically connected to the redistribution layer 50. In one embodiment, the redistribution layer 50 may be directly in contact with the rib structure 30 and electrically connected to the rib structure 30.

The semiconductor device 100 in the embodiment of the disclosure is a face-down structure as shown in FIG. 1A, and the dielectric layer 10 (and the redistribution layer 50 and the solder balls 60) may be disposed under the first die 21. However, the disclosure is not limited thereto.

FIG. 1B illustrates a cross-section view of the semiconductor device 100′ according to another embodiment of the disclosure. The semiconductor device 100′ shown in FIG. 1B is a face-up structure, and the dielectric layer 10′ (and the redistribution layer 50 and the solder balls 60) may be disposed on the molding layer 40. Other elements similar to those of semiconductor device 100 as shown in FIG. 1A would not be narrated herein.

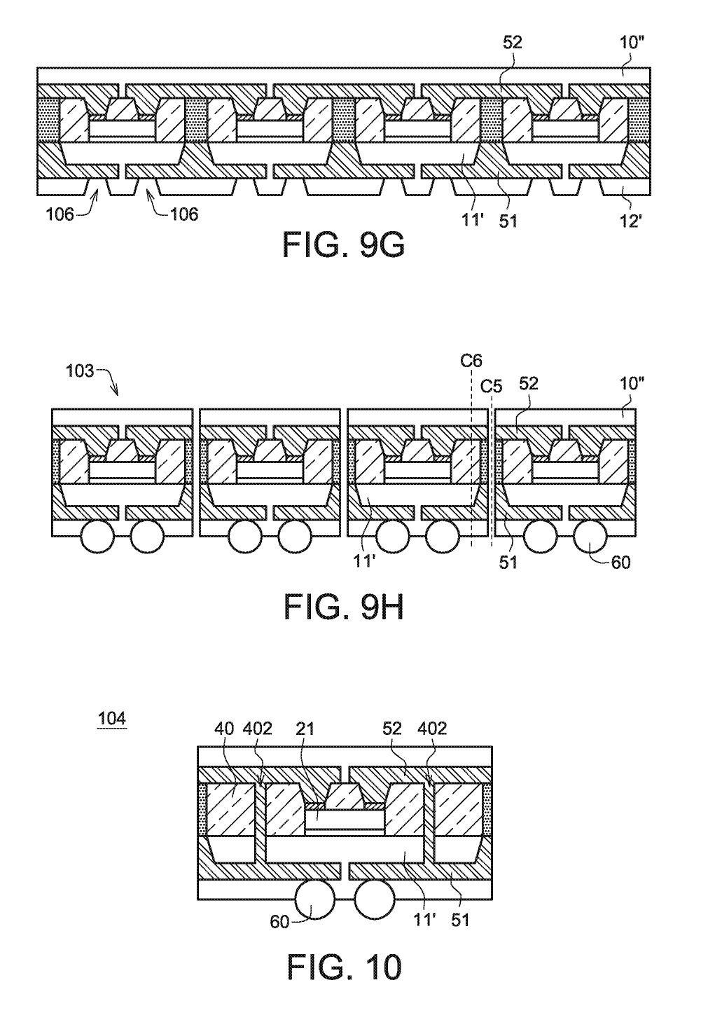

FIG. 10 illustrates a top view of the semiconductor device 100 according to the embodiment of the disclosure. FIG. 1A may be a cross-sectional view of the semiconductor device 100 along A-A′ line in FIG. 10. As shown in FIG. 10, the rib structure 30 may be formed of a plurality of first ribs 30-1 and second ribs 30-2. The second ribs 30-2 intersect the first ribs 30-1, and an extending direction of the first ribs 30-1 may be different from an extending direction of the second ribs 30-2. For example, the first ribs 30-1 may be arranged along a direction parallel with X-axis, while the second ribs 30-2 may be arranged along a direction parallel with Y-axis. That is, the first ribs 30-1 may be perpendicular to the second ribs 30-2, so that a web-shaped rib structure 30 may be formed.

However, the disclosure is not limited thereto. In other embodiments of the disclosure, the rib structure 30 may be formed of a plurality of third ribs (not shown) arranged in concentric circles, and the first die 21 may be formed between two of the third ribs.

In FIG. 1A, the rib structure 30 of the semiconductor device 100 encloses only one first die 21, so the top view of the semiconductor device 100 may be shown as the structure in FIG. 10. That is, there is only one first die 21 disposed in the single web enclosed by the first ribs 30-1 and the second ribs 30-2. When the semiconductor device 100 includes a plurality of first dies 21, the first dies 21 may be separated from each other by the rib structure 30 (the first ribs 30-1 or the second ribs 30-2). However, the disclosure is not limited thereto.

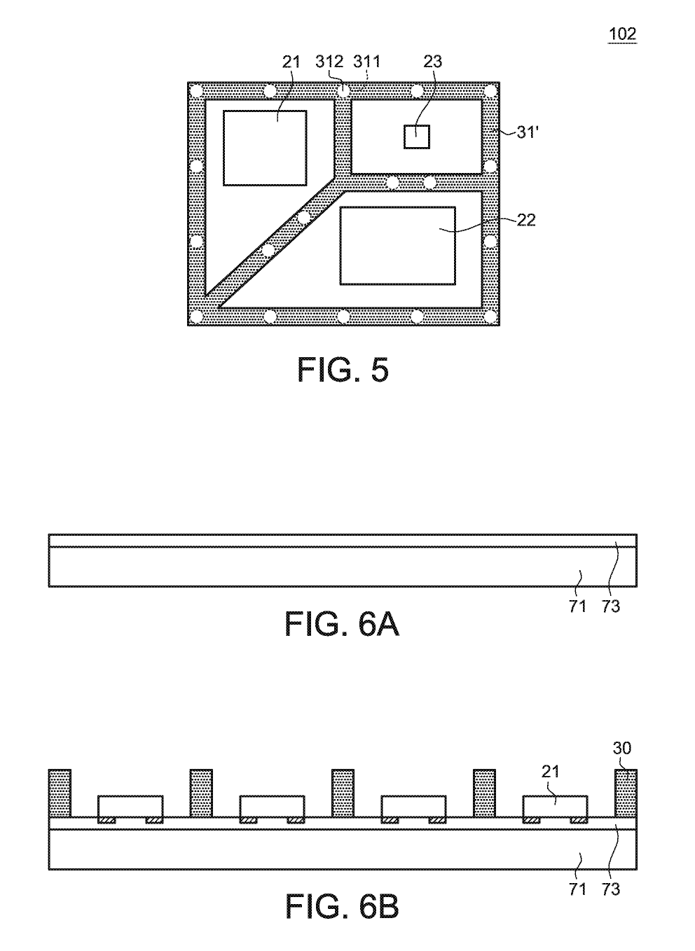

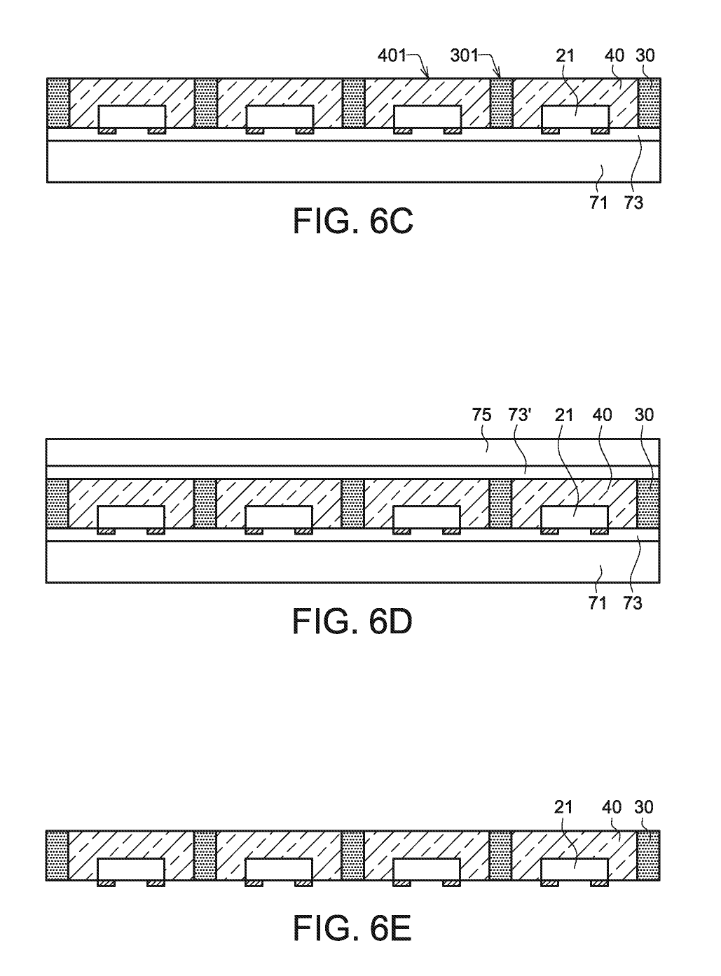

FIG. 2A illustrates a cross-section view of the semiconductor device 101 according to yet another embodiment of the disclosure. FIG. 2B illustrates a partial top view of the semiconductor device 101 according to the embodiment of the disclosure. FIG. 2A may be a cross-sectional view of the semiconductor device 101 along B-B′ line in FIG. 2B. In the embodiment shown in FIG. 2A, the rib structure 30 may enclose a plurality of first dies 21. Hence, there are first dies 21 (such as four dies 21 here) disposed in the single web enclosed by the first ribs 30-1 and the second ribs 30-2.

In the multi-chip module (MCM), it is easier to generate die shift and warpage in molded wafers since the wafers are smaller. These problems may be effectively solved by the structures according to the disclosure (such as the structures shown in FIG. 2A and FIG. 2B).

Similarly, the semiconductor device 101 shown in FIG. 2A is a face-down structure, and the dielectric layer 10, the redistribution layer 50 and the solder balls 60 may be disposed under the first die 21. However, the semiconductor device 101 may also be a face-up structure, and would not be narrated herein.

Further, a top surface 401 of the molding layer 40 and a top surface 301 of the rib structure 30 may be aligned with each other (coplanar) as shown in FIG. 1A and FIG. 2A. However, the disclosure is not limited thereto. In some embodiments of the disclosure, the top surface 401 of the molding layer 40 may be lower or higher than the top surface 301 of the rib structure 30, which depends on the design requirements.

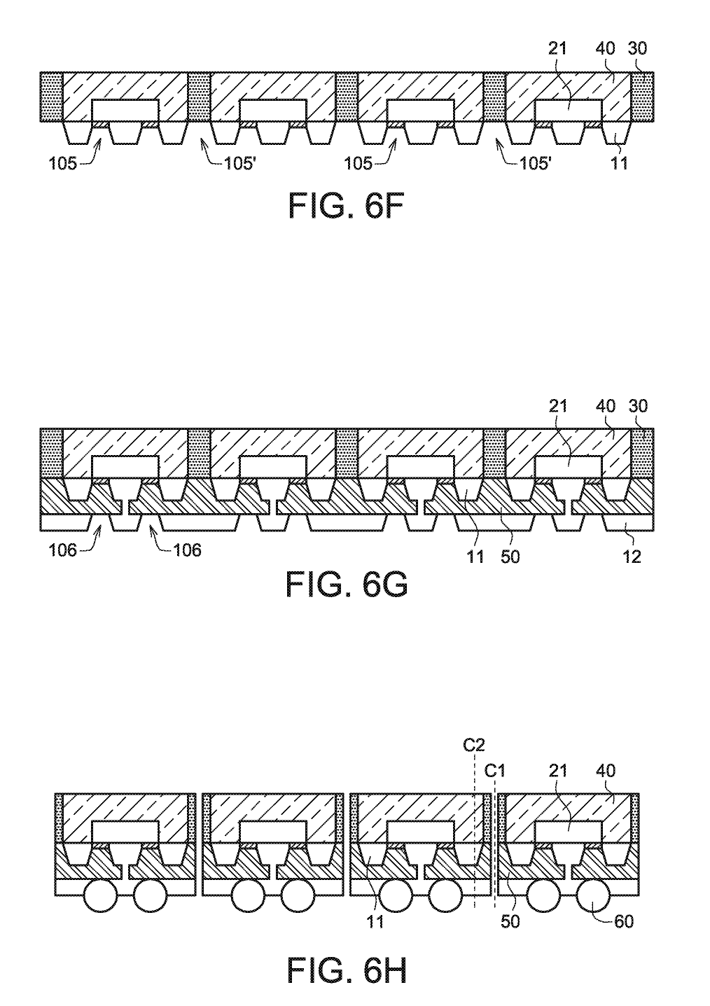

In the embodiments mentioned above, the rib structure 30 may be the structure made of single material. However, the disclosure is not limited thereto. FIG. 3 illustrates a cross-section view of the rib structure 31 according to one embodiment of the disclosure. In this embodiment, the rib structure includes a conductive material 312 and a through hole 311 filled with the conductive material 312. In one embodiment, the conductive material 312 may be indium tin oxide (ITO), metal or metal alloy, such as copper, copper alloy.

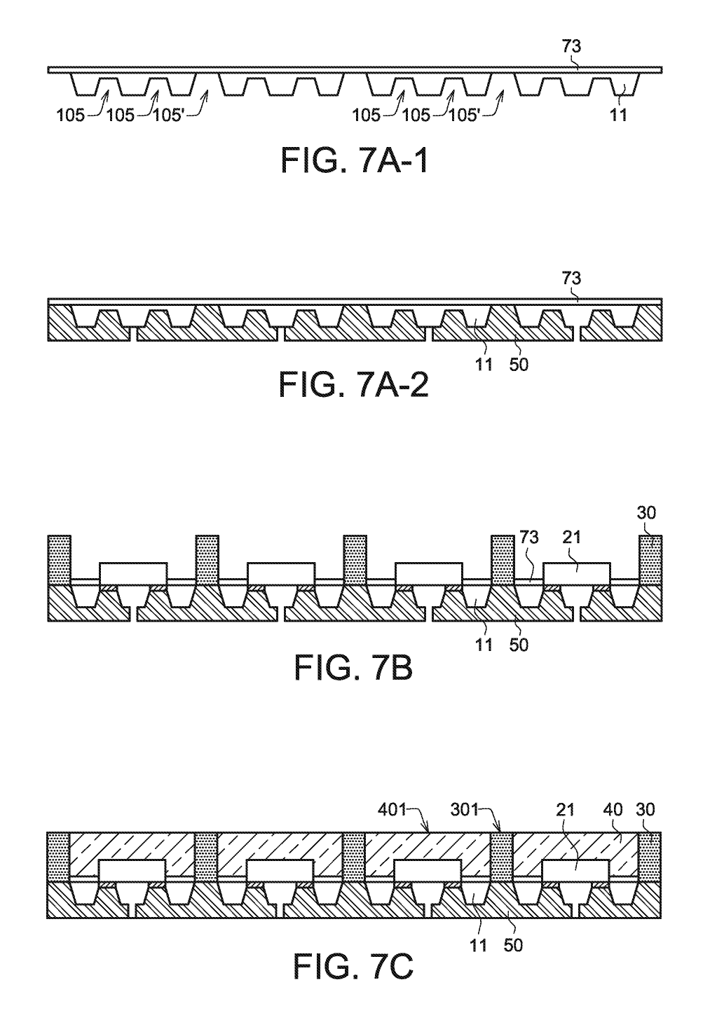

Generally, the rib structure 31 is non-conductive, and the elements disposed on both sides of the rib structure 31 may be electrically connected to each other by the through hole 311 and the conductive material 312. For example, the through hole 311 and the conductive material 312 may be electrically connected to the redistribution layer 50 to form a stacked molding type (as show in FIG. 4).

In contrast, when the rib structure 30 is formed of single material and the single material is conductor (such as metal) or semiconductor, the elements disposed on both sides of the rib structure 30 may be directly electrically connected to each other. For example, the rib structure 30 may be directly electrically connected to the redistribution layer 50 for shielding.

FIG. 4 illustrates a schematic diagram of a semiconductor stacked structure 200 according to one embodiment of the disclosure. The semiconductor stacked structure 200 may include a plurality of semiconductor devices 100 stacked on top of each other in this embodiment. As shown in FIG. 4, each of the semiconductor devices 100 includes a rib structure 31 and a plurality of solder balls 60. Two semiconductor devices 100 stacked on top of each other may be electrically connected to each other by the solder balls 60, the distribution layer 50 and the conductive material 312 of the rib structure 31. In other embodiments, the rib structure 30 may be substituted for the rib structure 31. Since the rib structure 30 is formed of single material and the single material is conductor (such as metal) or semiconductor, the two semiconductor devices 100 may be directly electrically connected to each other without additional through holes 311 and conductive material 312.

It should be noted that the numbers of the semiconductors 100, the method for stacking the semiconductors 100 and the numbers of the first dies 21 are not limited to the structure as shown in FIG. 4.

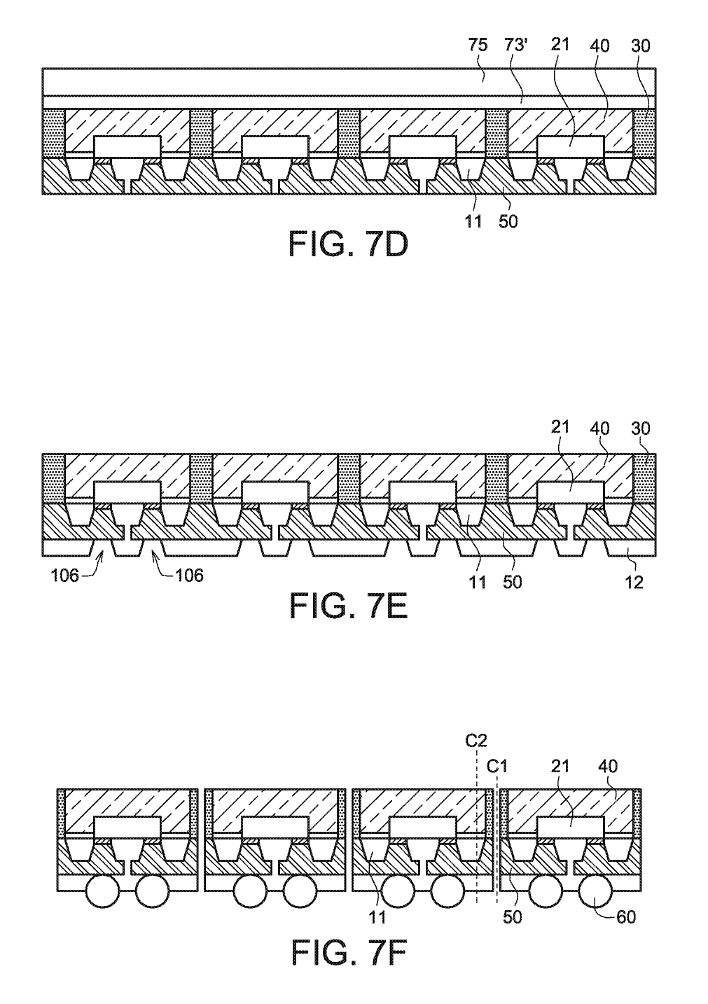

FIG. 5 illustrates a cross-section view of the semiconductor device 102 according to still another embodiment of the disclosure. In this embodiment, the semiconductor device 102 includes a first die 21, a second die 22 and a third die 23. The first die 21, the second die 22 and the third die 23 are disposed adjacent to one another, but the rib structure 31′ separates the first die 21, the second die 22 and the third die 23 from one another.

Here, the first die 21, the second die 22 and the third die 23 may be dies having different functionalities. For example, the first die 21 may be a radio frequency (RF) die, the second die 22 may be a digital die, and the third die 23 may be a passive element. The passive element may be a surface-mounted device (SMD), such as an antenna. However, the disclosure is not limited thereto. The numbers, functionalities and sizes of the first die 21, the second die 22 and the third die 23 may be adjusted depending on the design requirements.

The shape of the rib structure 31′ shown in FIG. 5 is different from the structures shown in the embodiments above, and the first die 21, the second die 22 and the third die 23 are separated from one another by the rib structure 31′. Here, the rib structure 31′ may include the through hole 311 and the conductive material 312.

In some embodiments, the rib structure 31′ may be metal and without the through hole 311 and the conductive material 312. When the rib structure 31′ is metal (or semiconductor), the rib structure 31′ may be a shielding structure between the first die 21 and the second die 22, between the second die 22 and the third die 23, or between the third die 23 and the first die 21. For example, when the first die 21, the second die 22 and the third die 23 are high frequency dies, the rib structure 31′ formed of metal material may work as one shielding structure; when the first die 21, the second die 22 and the third die 23 are low frequency dies, the rib structure 31′ formed of semiconductor may work as another shielding structure.

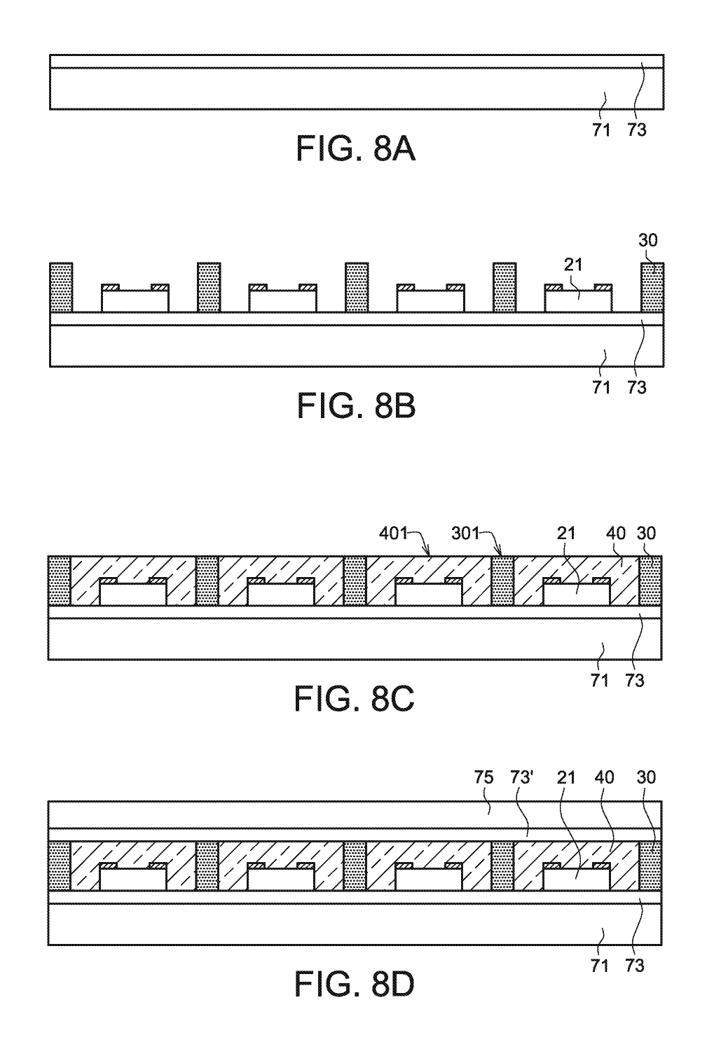

FIG. 6A to FIG. 6H illustrate a process for manufacturing a semiconductor device in one embodiment according to the disclosure. It should be noted that some elements may be omitted for illustrating the relationships between other elements more clearly.

First, a carrier 71 is provided and an adhesive tape 73 is formed on the carrier 71 as shown in FIG. 6A. Then, a rib structure 30 and first dies 21 are formed on the adhesive tape 73. Here, the rib structure 30 encloses the first dies 21, and the first dies 21 are formed as a face-down type on the adhesive layer 73.

As shown in FIG. 6C, a molding layer 40 is formed on the first dies 21. Here, the rib structure 30 is formed of a first material, the molding layer 40 is formed of a second material, and a Young's modulus of the first material is larger than a Young's modulus of the second material.

The spaces between the first dies 21 and the rib structure 30 are filled with the molding layer 40, and a top surface 401 of the molding layer 40 and a top surface 301 of the rib structure 30 are aligned with each other (coplanar). However, the disclosure is not limited thereto. In some embodiments of the disclosure, the top surface 401 of the molding layer 40 may be lower or higher than the top surface 301 of the rib structure 30. Then, the molding layer 40 is pre-cured.

As shown in FIG. 6D, a cover layer 75 is formed on the rib structure 30 and the molding layer 40 by another adhesive tape 73′. Then, the molding layer 40 is post cured. After post curing the molding layer 40, the cover layer 75, the carrier 71 and the adhesive tapes 73, 73′ are removed as shown in FIG. 6E.

It should be noted that the cover layer 75 used here is for preventing the semiconductor device from die shift and warpage. That is, the manufacturing step shown in FIG. 6D may be omitted in some embodiments.

Then, a first dielectric layer 11 is formed, such that the rib structure 30 and the first dies 21 are disposed on the first dielectric layer 11 as shown in FIG. 6F. Here, first holes 105 and second holes 105′ may be formed on the first dielectric layer 11 by exposure development, etching or layer processes. The first holes 105 may expose the electrodes of the first dies 21 and be the passageways for connecting the redistribution layer 50 formed in the following step (see FIG. 6G) with the first dies 21. The second holes 105′ may expose the rib structure 30 and be the passageways for connecting the redistribution layer 50 formed in the following step with the rib structure 30.

As shown in FIG. 6G, a redistribution layer 50 is formed on the first dielectric layer 11 and opposite to the first dies 21. In this embodiment, the redistribution layer 50 may be electrically connected to the first dies 21 by the first holes 105, and electrically connected to the rib structure 30 by the second holes 105′. Then, a second dielectric layer 12 is formed, such that the redistribution layer 50 is disposed between the first dielectric layer 11 and the second dielectric layer 12. Similarly, the second dielectric layer 12 may include holes 106, and the holes 106 may expose part of the redistribution layer 50.

As shown in FIG. 6H, a plurality of solder balls 60 are formed in the holes 106, and the solder balls 60 may be electrically connected to the redistribution layer 50. At last, the structure shown in FIG. 6H is cut along line C1, such that the semiconductor device 100 shown in FIG. 1A may be formed. In some embodiments, the structure shown in FIG. 6H may be cut along line C2, such that the semiconductor device may be formed without the rib structure 30.

FIG. 7A-1 to FIG. 7F illustrate a process for manufacturing a semiconductor device in another embodiment according to the disclosure. Similarly, some elements may be omitted for illustrating the relationships between other elements more clearly.

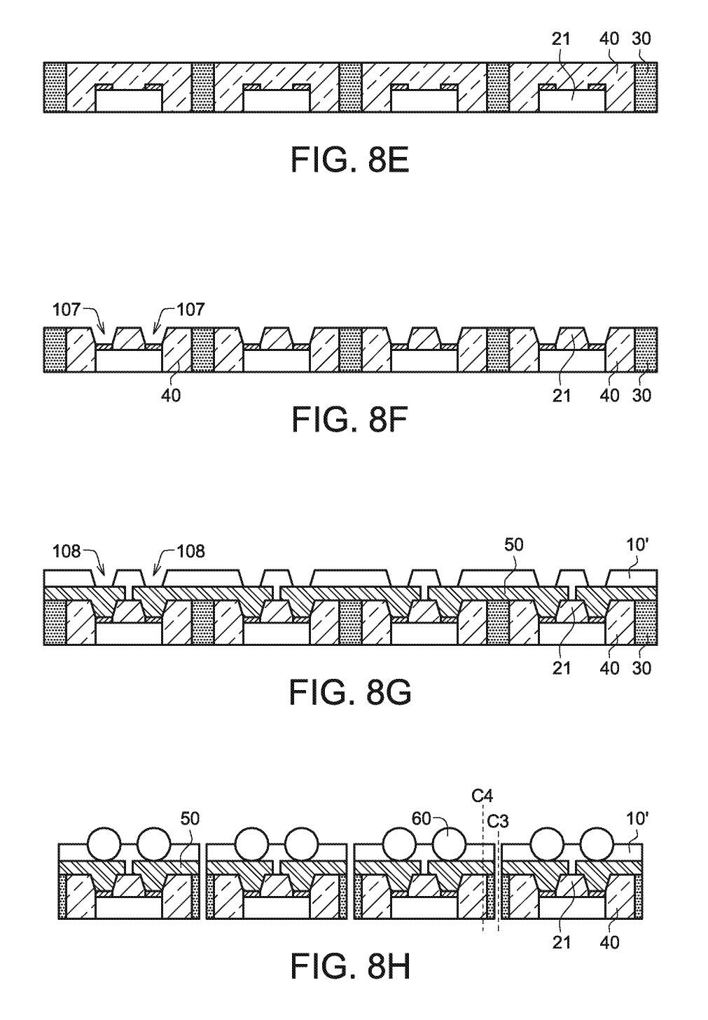

At first, a first dielectric layer 11 is formed as shown in FIG. 7A-1. The first dielectric layer 11 includes first holes 105 and second holes 105′. Positions of the first holes 105 may correspond to positions of first dies 21 formed in the following step (see FIG. 7B), and positions of the second holes 105′ may correspond to positions of a rib structure 30 formed in the following step (see FIG. 7B). Then, a redistribution layer 50 is formed on the first dielectric layer 11 by an adhesive tape 73 as shown in FIG. 7A-2. The first holes 105 and the second holes 105′ may be filled with the redistribution layer 50.

As shown in FIG. 7B, the rib structure 30 and first dies 21 are formed on the adhesive tape 73. Appropriate temperature and pressure should be applied at this time, such that the first dies 21 may be electrically connected to the redistribution layer 50 by the first holes 105, the rib structure 30 may be electrically connected to the redistribution layer 50 by the second holes 105, and the first dies 21 are enclosed by the rib structure 30. Here, the first dies 21 are not electrically connected to the rib structure 30. In this embodiment, the first dies 21 are formed as a face-down type on the first dielectric layer 11. Further, the rib structure 30 and the first dies 21 are formed on the first dielectric layer 11 and opposite to the redistribution layer 50.

As shown in FIG. 7C, a molding layer 40 is formed on the first dies 21. In this embodiment, the rib structure 30 is formed of a first material, the molding layer 40 is formed of a second material, and a Young's modulus of the first material is larger than a Young's modulus of the second material.

The spaces between the first dies 21 and the rib structure 30 are filled with the molding layer 40, and a top surface 401 of the molding layer 40 and a top surface 301 of the rib structure 30 are aligned with each other (coplanar). However, the disclosure is not limited thereto. In some embodiments of the disclosure, the top surface 401 of the molding layer 40 may be lower or higher than the top surface 301 of the rib structure 30. Then, the molding layer 40 is pre-cured.

As shown in FIG. 7D, a cover layer 75 is formed on the rib structure 30 and the molding layer 40 by an adhesive tape 73′. It should be noted that the cover layer 75 used here is for preventing the semiconductor device from die shift and warpage. That is, the manufacturing step shown in FIG. 7D may be omitted in some embodiments. Then, the molding layer 40 is post cured.

After post curing the molding layer 40, the cover layer 75 and the adhesive tape 73′ are removed, and a second dielectric layer 12 is formed, such that the redistribution layer 50 may be disposed between the first dielectric layer 11 and the second dielectric layer 12 as shown in FIG. 7E. The second dielectric layer 12 may include holes 106, and the holes 106 may expose part of the redistribution layer 50. Then, a plurality of solder balls 60 are formed in the holes 106, and the solder balls 60 may be electrically connected to the redistribution layer 50 by the holes 106.

At last, the structure shown in FIG. 7F is cut along line C1, such that the semiconductor device 100 shown in FIG. 1A may be formed. In some embodiments, the structure shown in FIG. 7F may be cut along line C2, such that the semiconductor device may be formed without the rib structure 30.

Although the embodiments shown in FIG. 6A to FIG. 7F are process steps for manufacturing the semiconductor device 100 in FIG. 1A and FIG. 10, the disclosure is not limited thereto. Instead, other semiconductor devices in the embodiments of the disclosure, such as semiconductor devices 101, 102, may be formed by similar process steps, which would not be narrated herein.

Further, the embodiments shown in FIG. 6A to FIG. 7F are process steps for manufacturing the face-down semiconductor device 100, but the disclosure is not limited thereto. The following embodiments are process steps for manufacturing the face-up semiconductor device (such as the semiconductor device 100′ shown in FIG. 1B).

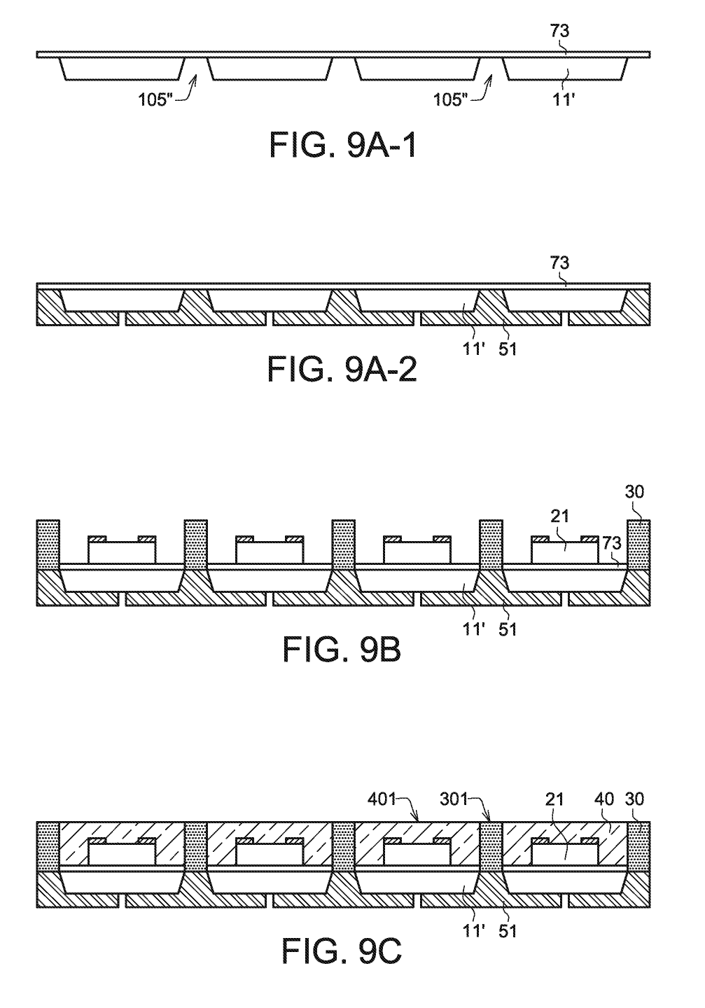

FIG. 8A to FIG. 8H illustrate a process for manufacturing a semiconductor device in one embodiment according to the disclosure. It should be noted that some elements may be omitted for illustrating the relationships between other elements more clearly.

The process steps shown in FIG. 8A to FIG. 8E may be similar to the process steps shown in FIG. 6A to FIG. 6E. The difference between the process steps shown in FIG. 8A to FIG. 8E and the process steps shown in FIG. 6A to FIG. 6E is that the first dies 21 are formed as a face-up type on the adhesive layer 73 in FIG. 8A to FIG. 8E. Other similar steps would not be narrated herein.

Similarly, the process step shown in FIG. 8D may be omitted in some embodiments of the disclosure. That is, the adhesive tape 73′ and the cover layer 75 may not be formed on the rib structure 30 and the molding layer 40.

As shown in FIG. 8F, a plurality of holes 107 are formed on the molding layer 40, such that the holes 107 may expose the electrodes of the first dies 21.

As shown in FIG. 8G, a redistribution layer 50 is formed on the molding layer 40. In this embodiment, the redistribution layer 50 may be electrically connected to the first dies 21 by the holes 107. Then, a dielectric layer 10′ is formed on the redistribution layer 50. Here, the dielectric layer 10′ may include holes 108, and the holes 108 may expose part of the redistribution layer 50.

As shown in FIG. 8H, a plurality of solder balls 60 are formed in the holes 108, and the solder balls 60 may be electrically connected to the redistribution layer 50. At last, the structure shown in FIG. 8H is cut along line C3, such that the semiconductor device 100′ shown in FIG. 1B may be formed. In some embodiments, the structure shown in FIG. 8H may be cut along line C4, such that the semiconductor device may be formed without the rib structure 30.

FIG. 9A-1 to FIG. 9H illustrate a process for manufacturing a semiconductor device in another embodiment according to the disclosure. Similarly, some elements may be omitted for illustrating the relationships between other elements more clearly.

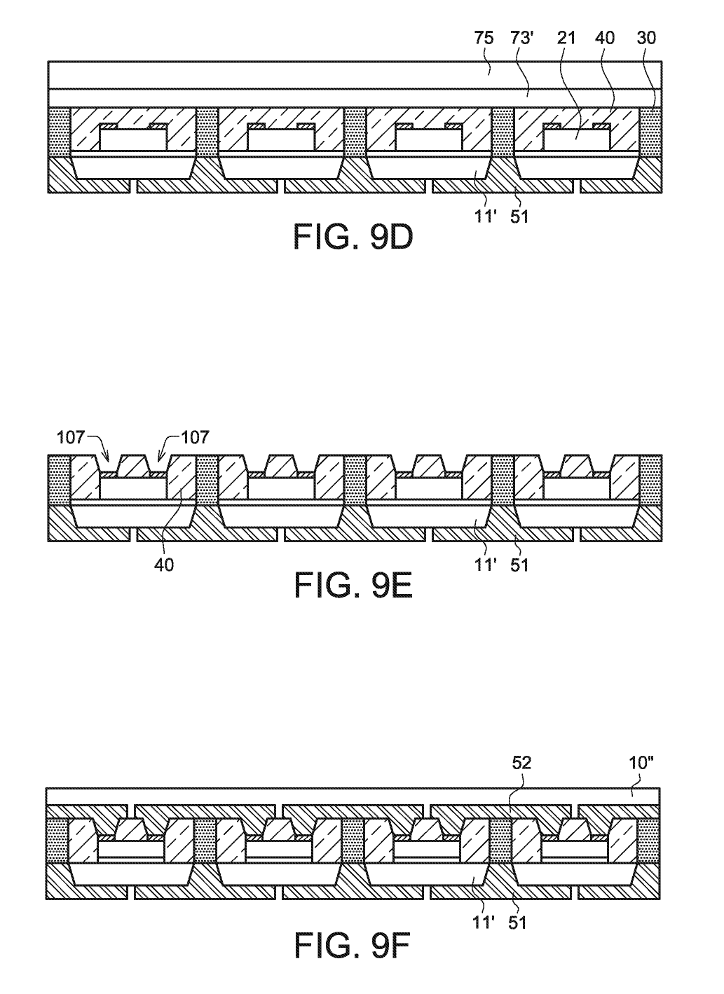

At first, a first dielectric layer 11′ is formed as shown in FIG. 9A-1. The first dielectric layer 11′ includes holes 105″. Positions of the holes 105″ may correspond to positions of a rib structure 30 formed in the following step (see FIG. 9B). Then, a first redistribution layer 51 is formed on the first dielectric layer 11′ by an adhesive tape 73 as shown in FIG. 9A-2. The holes 105″ may be filled with the first redistribution layer 51.

As shown in FIG. 9B, the rib structure 30 and first dies 21 are formed on the adhesive tape 73. The first dies 21 are enclosed by the rib structure 30, and appropriate temperature and pressure should be applied at this time, such that the rib structure 30 may be electrically connected to the first redistribution layer 51 by the holes 105″. Here, the first dies 21 are not electrically connected to the rib structure 30, and the first dies 21 are formed as a face-up type on the adhesive tape 73 and the first dielectric layer 11′. In this embodiment, the rib structure 30 and the first dies 21 are formed on the first dielectric layer 11′ and opposite to the first redistribution layer 51.

As shown in FIG. 9C, a molding layer 40 is formed on the first dies 21. Similarly, the rib structure 30 is formed of a first material, the molding layer 40 is formed of a second material, and a Young's modulus of the first material is larger than a Young's modulus of the second material.

The spaces between the first dies 21 and the rib structure 30 are filled with the molding layer 40, and a top surface 401 of the molding layer 40 and a top surface 301 of the rib structure 30 are aligned with each other (coplanar). However, the disclosure is not limited thereto. In some embodiments of the disclosure, the top surface 401 of the molding layer 40 may be lower or higher than the top surface 301 of the rib structure 30. Then, the molding layer 40 is pre-cured.

As shown in FIG. 9D, a cover layer 75 is formed on the rib structure 30 and the molding layer 40 by an adhesive tape 73′. It should be noted that the cover layer 75 used here is for preventing the semiconductor device from die shift and warpage. That is, the manufacturing step shown in FIG. 9D may be omitted in some embodiments. Then, the molding layer 40 is post cured.

After post curing the molding layer 40, the cover layer 75 and the adhesive tape 73′ are removed, and a plurality of holes 107 are formed on the molding layer 40, such that the electrodes of the first dies 21 may be exposed by the holes 107 as shown in FIG. 9E.

As shown in FIG. 9F, a second redistribution layer 52 is formed on the molding layer 40. In this embodiment, the second redistribution layer 52 may be electrically connected to the first dies 21 by the holes 107. Then, a dielectric layer 10″ is formed on the second redistribution layer 52. It should be noted that the second redistribution layer 52 is directly in contact with the rib structure 30 and the molding layer 40, but the disclosure is not limited thereto. In some embodiment, the dielectric layer 10″ may be disposed between the second redistribution layer 52 and the molding layer 40, and the second redistribution layer 52 may be electrically connected to the first dies 21 and the rib structure 30 by forming holes on the dielectric layer 10″.

As shown in FIG. 9G, a second dielectric layer 12′ is formed, such that the first redistribution layer 51 may be disposed between the first dielectric layer 11′ and the second dielectric layer 12′. The second dielectric layer 12′ may include holes 106, and the holes 106 may expose part of the first redistribution layer 51. Then, a plurality of solder balls 60 are formed in the holes 106. The solder balls 60 may be electrically connected to the first redistribution layer 51 by the holes 106, and electrically connected to the first dies 21 by the rib structure 30 and the second redistribution layer 52.

At last, the structure shown in FIG. 9H is cut along line C5, such that a semiconductor device 103 in one embodiment of the disclosure may be formed. In some embodiments, the structure shown in FIG. 9H may be cut along line C6, such that the semiconductor device may be formed without the rib structure 30.

It should be noted that although the solder balls 60 of the semiconductor device 103 are electrically connected to the first redistribution layer 51 by the holes 106, and electrically connected to the first dies 21 by the rib structure 30 and the second redistribution layer 52 in the embodiment above, the disclosure is not limited thereto.

FIG. 10 illustrates a cross-section view of the semiconductor device 104 according to another embodiment of the disclosure. Similar with the semiconductor device 103, the semiconductor device 104 is another face-up semiconductor device. In this embodiment, through holes 402 may be formed in the molding layer 40 and the first dielectric layer 11′ of the semiconductor device 104, and the through holes 402 may be filled with conductive material, such that the second redistribution layer 52 and the first redistribution layer 51 disposed on top and bottom side of the molding layer 40 may be electrically connected to each other. That is, the solder balls 60 may be electrically connected to the first redistribution layer 51, and electrically connected to the first dies 21 by conductive material in the through holes 402, not by the rib structure 30.

Table 1 shows the results of die shifts occurring in the semiconductor devices manufactured by different manufacturing processes. No rib structure and cover layer are formed in Process 1; a rib structure is formed in Process 2; a rib structure and a cover layer having width of 0.2 mm are formed in Process 3; a rib structure and a cover layer having width of 0.5 mm are formed in Process 4; a rib structure and a cover layer having width of 0.775 mm are formed in Process 5. The die shifts of four dies (die 1 to die 4) from the center of the wafer toward outside are sequentially measured, and the results are shown in Table 1.

TABLE 1

amount of shift

| Process | die 1 | die 2 | die 3 | die 4 |
|---|---|---|---|---|
| Process 1 | 0.019 | 0.156 | 0.405 | 0.953 |
| Process 2 | 0.012 | 0.123 | 0.335 | 0.717 |
| Process 3 | 0.004 | 0.055 | 0.1507 | 0.2849 |
| Process 4 | 0.001 | 0.012 | 0.033 | 0.054 |
| Process 5 | 0.00015 | 0.00054 | 0.00118 | 0.00212 |

It may be shown from Table 1 that the die farthest from the center of wafer (die 4) has the largest die shift in each of the Processes. From the results of the die shifts of the dies farthest from the center of wafer (die 4) in all processes, it apparently shows that the die shifts of the dies farthest from the center of wafer in Processes 2 to 5 have significant decrease compared with Process 1. That is, it is apparently helpful for solving the problem of die shift by forming the rib structure and the cover layer. Further, the thicker of the cover layer, the more improvement may be shown for solving the problem of die shift as the results of Processes 3 to 5.

According the embodiments of the disclosure mentioned above, the deformation due to different coefficients of thermal expansion (CTE) of different materials during the manufacturing processes may be effectively reduced by the rib structure or the cover layer, such that the problems of die shift and warpage in molded wafers may be solved.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor device, comprising:
at least one first die;
a rib structure enclosing the at least one first die and formed of a first material; and
a molding layer covering the at least one first die and formed of a second material; and
a redistribution layer electrically connected to the at least one first die;
wherein a Young's modulus of the first material is larger than a Young's modulus of the second material, and a sidewall of the rib structure is aligned with a sidewall of the redistribution layer.

2. The semiconductor device according to claim 1, wherein the first material is silicon, metal, metal alloy, or ceramic material.

3. The semiconductor device according to claim 1, wherein the at least one first die comprises a plurality of first dies, and the rib structure encloses the first dies.

4. The semiconductor device according to claim 1, further comprising:
a second die adjacent to the at least one first die;
wherein the rib structure separates the at least one first die from the second die.

5. The semiconductor device according to claim 1, wherein when the first material is non-conductive, the rib structure further comprises:
a conductive material; and
a through hole filled with the conductive material.

6. The semiconductor device according to claim 5, wherein the conductive material is indium tin oxide, metal or metal alloy.

7. The semiconductor device according to claim 1, further comprising:
a plurality of solder balls electrically connected to the redistribution layer.

8. The semiconductor device according to claim 7, further comprising:
a dielectric layer disposed under the at least one first die;
wherein the redistribution layer is disposed in the dielectric layer.

9. The semiconductor device according to claim 7, further comprising:
a dielectric layer disposed on the molding layer;
wherein the redistribution layer is disposed in the dielectric layer.

10. The semiconductor device according to claim 1, wherein a top surface of the molding layer and a top surface of the rib structure are coplanar.

11. The semiconductor device according to claim 1, wherein the rib structure is formed of a plurality of first ribs and second ribs intersecting the first ribs, and an extending direction of the first ribs is different from an extending direction of the second ribs.

12. (canceled)

13. A semiconductor stacked structure comprising a plurality of semiconductor devices stacked together, each of the semiconductor devices comprising:
at least one first die;
a rib structure enclosing the at least one first die and formed of a first material;
a molding layer covering the at least one first die and formed of a second material;
a redistribution layer electrically connected to the at least one first die; and
a plurality of solder balls electrically connected to the redistribution layer;
wherein a Young's modulus of the first material is larger than a Young's modulus of the second material, a sidewall of the rib structure is aligned with a sidewall of the redistribution layer, and the semiconductor devices are electrically connected to each other by the rib structure, the redistribution layer and the solder balls.

14. A method of manufacturing a semiconductor device, comprising:
forming a first adhesive tape on a carrier;
forming a rib structure and at least one first die on the first adhesive tape, wherein the rib structure encloses the at least one first die;
forming a molding layer on the at least one first die, wherein spaces between the at least one first die and the rib structure are filled with the molding layer;
curing the molding layer;
removing the first adhesive tape and the carrier; and
forming a redistribution layer and a plurality of solder balls electrically connected to the at least one first die;
wherein the rib structure is formed of a first material, the molding layer is formed of a second material, and a Young's modulus of the first material is larger than a Young's modulus of the second material.

15. The method according to claim 14, further comprising:
forming a cover layer on the rib structure and the molding layer by a second adhesive tape before removing the first adhesive tape and the carrier;
post curing the molding layer; and
removing the second adhesive tape and the cover layer.

16. The method according to claim 14, further comprising:
forming a first dielectric layer, such that the rib structure and the at least one first die are formed on the first dielectric layer, wherein the redistribution layer is formed on the first dielectric layer and opposite to the at least one first die; and
forming a second dielectric layer, such that the redistribution layer is formed between the first dielectric layer and the second dielectric layer.

17. The method according to claim 16, wherein the first dielectric layer comprises a plurality of holes, and the redistribution layer is electrically connected to the at least one first die by the holes.

18. The method according to claim 16, wherein the second dielectric layer comprises a plurality of holes, and the solder balls are electrically connected to the redistribution layer by the holes.

19. The method according to claim 14, further comprising:
forming a plurality of holes on the molding layer, such that the holes expose an electrode of the at least one first die; and
forming the redistribution layer on the molding layer, wherein the redistribution layer is electrically connected to the at least one first die by the holes.
